(19) United States
(12) Patent Application Publication
(10) Pub. No.: US 2023/0272519 A1
(43) Pub. Date: Aug. 31, 2023

(54) DENSE TARGET

(71) Applicant: SOLERAS ADVANCED COATINGS BV, Deinze (BE)

(72) Inventors: Wilmert DE BOSSCHER, Drongen (BE); Ignacio CARETTI GIANGASPRO, Antwerpen (BE); Jai Shankar SUBRAMANIAN, Solon, OH (US); Jeffrey Dieter EDEL, Akron, OH (US)

(21) Appl. No.: 18/016,078

(22) PCT Filed: Jul. 14, 2021
(86) PCT No.: PCT/EP2021/069590

§ 371 Date: Jan. 13, 2023

(30) Foreign Application Priority Data
Jul. 14, 2020 (BE) 2020/5525

(51) Int. Cl. C23C 14/34; C04B 41/91; C04B 37/02

(52) U.S. Cl. CPC C23C 14/3414; C04B 41/91; C04B 37/02; C04B 2235/94

(57) ABSTRACT

A sputtering target includes at least one single piece with a length of at least 600 mm. The sputtering target has a backing structure provided with target material for sputtering. At least 40% of the mass of the target material includes a so-called target volatile material which shows, at pressures between 700 hPa and 1300 hPa, either a sublimation temperature, or decomposition temperature below its melting point or a melting temperature and an absolute boiling temperature being close to each other. The sputtering target has a target material density of at least 95% of the theoretical density of the target material. The sputtering target includes a bonding layer with a thickness of 0 to 500 μm between the backing structure and the target material.

### FIELD OF THE INVENTION

The invention relates to the field of sputtering. More specifically it relates to sputtering targets and manufacture thereof, especially for instance targets including ceramic material.

### BACKGROUND OF THE INVENTION

Physical vapor deposition by means of sputtering has become a standard technique to customize the properties of, for example, glass panes or other rigid or flexible materials. ‘Sputtering’ refers to the ballistic ejection of coating material atoms out of a target by means of positively charged ions,—usually argon—that are accelerated by an electric field towards a negatively charged target. The positive ions are formed by electron-ion impact ionization in the low pressure gas phase. The ejected atoms impinge on the substrate to be coated where they form a dense, well adhering coating.

The coating may form layers on the substrate, so the properties of the material (e.g. optical and/or mechanical properties) can be tailored.

Some types of layers are difficult to obtain, for example dielectric layers. For instance, oxidic films are often desired because they can be made with selectable transparency, making them suitable for optical applications such as lenses, filters, and the like. However, deposition of oxidic films is difficult for reasons explained in the following.

It is possible to provide oxide layers by deposition, by sputtering a metal target with a gas mixture including oxygen. This may result in severe hysteresis behavior, which leads to process instability. The relatively high amount of oxygen gas needed to bring the metallic target into the so-called poisoned state to grow a metal oxide layer leads commonly to a drop of sputter rate. The document “OBERSTE-BERGHAUS et al., Film Properties of Zirconium Oxide Top Layers from Rotatable Targets, 2015 Society of Vacuum Coaters, 58th Annual Technical Conference Proceedings, Santa Clara, Calif. Apr. 25-30, 2015, p. 228-234” discloses that the use of ceramic targets can alleviate or fully remove the hysteresis behavior, significantly reduce the amount of reactive gas and allow up to three times higher film deposition rates over sputtering processes using metal targets.

For large area applications such as architectural glass, the coatings must be sputtered onto large substrates, and it is thus required to provide also large targets so that the sputtering is homogeneous. However, large target ceramic pieces are difficult to obtain. Sintering can be used to provide small target pieces that need to be assembled to form a larger sized target assembly, for example as a combination of tiles (for planar targets assemblies) or as stacked sleeves (for cylindrical target assemblies on a cylindrical carrier). These targets are prone to arcing especially at their many edges at junctions in the smaller material pieces. US2012055783A1 discloses thermal spraying over a backing structure to provide a ceramic target, and US2007034500A1 discloses sintering of silicon oxide target by HIP. However, long ceramic sputter targets manufactured by common methods such as sintering or thermal spray often present porosities and a density lower than the theoretical density of the bulk material. In addition, using sintering in order to produce larger material pieces, may require the introduction of organic bonding agents, impacting the purity of the resulting target material. This is even more significant in the case of materials that decompose thermally or sublimate at the manufacturing pressures and temperatures employed. The lower density and porosity may be linked to a negative performance during sputtering due to reduced thermal conductivities, material spitting, dust formation and subsequent increased arcing rates. JP2013147368A discloses the possibility of obtaining a long ceramic cylindrical target material prepared by cold isostatic pressing (CIP) of specially prepared granules, followed by sintering. Similarly, JP2018009251A discloses a cylindrical molded product for a target prepared by CIP followed by sintering. However, it is necessary to join the target material to a backing tube with soldering or brazing material as adhesive, which requires extra steps.

### SUMMARY OF THE INVENTION

It is an object of embodiments of the present invention to provide a dense sputtering target that can be used for coating large areas with reduced number of parts or made as a single piece, and that exhibits a good bonding of target material on a backing structure.

It is an advantage that even materials with high evaporation rates or even sublimation can be used as target material in sputtering targets with combined large size and dense material, for providing a more stable sputtering process, e.g. providing sputtering with reduced poisoning, arcing or the like and/or allowing a higher sputter power density to be used.

In a first aspect, a sputtering target is provided. It comprises at least one single piece with a length of at least 600 mm, e.g. 800 mm or larger. The sputtering target comprises a backing structure provided with target material for sputtering, wherein at least 40% of the mass, e.g. at least 50%, at least 60%, at least 70%, at least 80% or at least 90%, of the mass, of this target material comprises material which in the following receives the name of ‘target volatile material’ showing either a sublimation point temperature (or sublimation temperature), or a melting point temperature (or melting temperature) and an absolute boiling point temperature (or boiling temperature) or decomposition temperature, the absolute boiling and/or decomposition temperature of said target material being less than 30% higher, or being lower, than its melting temperature. These ranges can be defined at pressures close to atmospheric pressure, e.g. at pressures typical for thermal spraying processes, e.g. between 700 hPa and 1300 hPa. The target material has an overall target material density of at least 90%, for example at least 95%, or at least 98%, or at least 99% of its theoretical density. The sputtering target comprises a bonding layer with a thickness of 0 μm to 500 μm, for instance a thickness of 0 μm to 300 μm, between the backing structure and the target material. This means that the sputtering target may comprise no bonding layer at all between the target material and the backing structure, or a thin bonding layer, thinner than the bonding layers that are usually implemented. It is an advantage of embodiments of the present invention that the bonding layer improves attachment of the target material to the backing structure. Furthermore, if a bonding layer is being implemented in between the target material and the backing structure; it consists of a material that remains stable (meaning: not showing any degradation or melting) at any temperature below 500° C. This is in contrast to typically used bonding concepts using materials containing e.g. Indium, Tin, elastomers or epoxy.

It is an advantage of embodiments of the present invention that a dense target can be provided as a single large piece, for example as large as the backing structure, with no need to provide the target as a combination of smaller target tiles or segments. It is an advantage of embodiments of the present invention that a high density target has low porosity and hence allows a more stable process during sputtering.

In some embodiments, the target volatile material for sputtering is a ceramic material. In particular, the target volatile material for sputtering may comprise a metal oxide such as indium tin oxide, ZnO, or SnO₂, or In₂O₃, or WO₃ or other metal oxides.

It is an advantage of embodiments of the present invention that ceramic oxide targets can be provided with little or no embedded dust or pores, thereby reducing arcing and the like. It is an advantage of embodiments of the present invention that oxide targets and the like can be provided, e.g. for providing thin layers, e.g. thin transparent and/or conductive oxide layers.

It is an advantage of embodiments of the present invention that the target material of the sputtering target may comprise almost half or more than half, for example 60%, of said target volatile material which is difficult to provide, especially in large target pieces.

In some embodiments of the present invention, the target material has a resistivity lower than 1000 Ohm·cm. This gives the advantage that the sputtering target can be used for sputtering, with frequencies lower than RF frequencies.

In some embodiments of the present invention, the sputtering target comprises a backing structure having a thermal expansion coefficient similar to the thermal expansion coefficient of the target material. It is an advantage that the target material and the backing structure retain good adhesion.

In some embodiments of the present invention, the backing structure comprises or consists of steel. It is an advantage of embodiments of the present invention that an inexpensive material can be used as a backing structure for thermal-spraying of the target material. An adhesive material can be added between the backing structure, e.g. the steel backing structure, and the target material, forming a bonding layer and bridging the materials. The bonding layer may for example have a thermal expansion coefficient compatible with both the backing structure and the target material.

In some embodiments of the present invention the sputtering target may be tubular, e.g. a cylindrical tubular target for sputtering. In the latter case, the backing structure may have a tubular shape.

In a second aspect, a method of providing a target for sputtering is provided. The method comprises providing a backing structure, optionally providing a bonding layer with a thickness of 500 μm or less, for instance a thickness of 300 μm or less, thermal-spraying target material over the backing structure with or without the bonding layer, wherein at least part of the target material sublimates or the absolute boiling or decomposition temperature of said material is less than 30% higher or even lower than its melting temperature, thus obtaining a target product, and subsequently performing a hot isostatic pressure process on the target product, thus increasing the density of the target product to at least 90%, for example at least 95%, or at least 98%, or at least 99%, of its theoretical density.

It is an advantage that target material be used to produce the sputtering target by means of spraying instead of sintering, even if the material tends to sublimate or decompose at high temperatures with reduced melting. Thermal spraying of target volatile materials often results in insufficient melting of the material and severe dust formation. The incorporation of unmolten particles and/or dust into the sprayed coating negatively affects the contact between splats of the projected material of the sprayed target, causing a subsequent density decrease and porosity increase. It is an advantage of embodiments of the present invention that a high density target has low porosity and hence allows a more stable process during the actual sputtering.

It is an advantage of embodiments of the present invention that material which is difficult to provide by spraying can still provide a dense target as a single large piece with no need of providing the target as a combination of smaller target tiles or segments.

In some embodiments the method further comprises a preparation step on the surface of the target material, e.g. removing surface material, for instance by polishing or grinding, before performing hot isostatic pressing. Such step causes lower surface porosity. In some embodiments, the method further comprises coating the sprayed target with material thus providing an external layer with high density, for instance with a density higher than the density of the sprayed target material.

These steps advantageously reduce the open pores on the surface. In some embodiments, the open pores and roughness are removed by polishing, or covered with an overlay layer, without substantially filling said pores.

In some embodiments the method further comprises removing an external layer of the target after performing hot isostatic pressing.

The method in accordance with embodiments of the second aspect can be used to provide a sputtering target in accordance with embodiments of the first aspect of the present invention. It is an advantage of embodiments of the present invention that material which is difficult to provide by spraying, such as ceramic material, can still provide a dense target as a single large piece with no need of providing the target as a combination of smaller target tiles or segments.

In some embodiments, the method comprises providing a backing structure with a length of at least 600 mm, e.g. a length of 800 mm or larger. Providing a backing structure may comprise providing a steel backing structure. A steel backing structure has the advantage of presenting good mechanical properties for the hot isostatic pressure process.

Particular and preferred aspects of the invention are set out in the accompanying independent and dependent claims. Features from the dependent claims may be combined with features of the independent claims and with features of other dependent claims as appropriate and not merely as explicitly set out in the claims.

These and other aspects of the invention will be apparent from and elucidated with reference to the embodiment(s) described hereinafter.

### BRIEF DESCRIPTION OF THE DRAWINGS

FIG. 1 illustrates a planar target assembly formed by four pieces in accordance with embodiments of the present invention.

FIG. 2 illustrates a tubular target product in a hot isostatic pressure vessel in accordance with embodiments of the present invention.

FIG. 3 is a flowchart of a method of embodiments of the present invention for manufacturing targets.

FIG. 4 illustrates a perspective view of a mold or backing structure for providing a target in accordance with embodiments of the present invention.

FIG. 5 illustrates the cross section of a mold and the procedure steps to provide a target in accordance with embodiments of the present invention.

FIG. 6 illustrates a cross section of a tubular target product for providing a tubular target in accordance with embodiments of the present invention.

FIG. 7 illustrates a cross section of a tubular target product for providing a tubular target and refilling a used target, in accordance with embodiments of the present invention.

FIG. 8 illustrates a cross section of a tubular target in accordance with embodiments of the present invention.

FIG. 9 illustrates a cross section of a tubular target in accordance with embodiments of the present invention.

The drawings are only schematic and are non-limiting. In the drawings, the size of some of the elements may be exaggerated and not drawn on scale for illustrative purposes.

Any reference signs in the claims shall not be construed as limiting the scope. In the different drawings, the same reference signs refer to the same or analogous elements.

### DETAILED DESCRIPTION OF ILLUSTRATIVE EMBODIMENTS

The present invention will be described with respect to particular embodiments and with reference to certain drawings but the invention is not limited thereto but only by the claims. The dimensions and the relative dimensions do not correspond to actual reductions to practice of the invention.

Furthermore, the terms first, second and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

Moreover, the terms top, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. The term “comprising” therefore covers the situation where only the stated features are present and the situation where these features and one or more other features are present. Thus, the scope of the expression “a device comprising means A and B” should not be interpreted as being limited to devices consisting only of components A and B. It means that with respect to the present invention, the only relevant components of the device are A and B.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

In the description provided herein, numerous specific details are set forth. However, it is understood that embodiments of the invention may be practiced without these specific details. In other instances, well-known methods, structures and techniques have not been shown in detail in order not to obscure an understanding of this description.

Where in embodiments of the present invention reference is made to “backing structure”, reference is made to the structure on which target material for sputtering is provided. The backing structure holds the target material and can be functionally linked to a sputter source in a coating chamber. For example, the backing structure may have a circular or rectangular area over which the target material is provided, as in the so-called “planar targets”. Backing structures do not need to be flat. They may be molded to provide grooves. Targets with tube-like, e.g. cylindrical, backing structure are known as “tubular targets”. A backing structure may comprise a carrier. It may include a carrier and an extra layer for providing or improving adhesion between the target material and the carrier. In some embodiments, a backing structure may include a carrier and target material, for example the backing structure may be an eroded target over which new target material is provided, in accordance with embodiments of the present invention.

Where in embodiments of the present invention reference is made to “target volatile material”, reference is made to material which presents a sublimation temperature or a decomposition temperature and/or an absolute boiling temperature close to the melting temperature, for example the absolute boiling and/or decomposition temperature being less than 30% higher, or being lower, than the melting point temperature in degrees Celsius. In some embodiments, the boiling or decomposition temperature of the target volatile material may be less than 25%, or less than 20%, or less than 15% higher than the melting temperature.

It is noted that these temperatures are to be considered at pressures typically used in thermal spray processing. For example, these temperatures and temperature ranges are defined at atmospheric pressure. For example, these temperatures and temperature ranges may be defined at pressures between 700 and 1300 hPa.

Where in embodiments of the present invention reference is made to “theoretical density”, reference is made to the density of a material, corresponding to the limit attainable if no pores are present in the material. The theoretical density of a mixture takes into account the fractions and theoretical densities of each component of the mixture.

While metals can be cast, molded, extruded or formed into targets, some materials prove difficult to process in order to manufacture a target from them. Oxidic materials are a typical example, although the present invention is not limited to oxidic target material, and other ceramics can be used. Compression and heating of powdered material provide coalescence into targets, in a process known as sintering. However, it is difficult to provide large single-piece targets via sintering. In some cases, density is not optimal and the materials may present porosity; density is usually not homogeneous, and shrinkage and even crack formation may occur. Sintering can be used to provide for example target tiles with dimensions of e.g. 134.53 mm×145.05 mm or smaller. it is much easier to provide these small pieces by sintering, which have homogeneous composition and density, and may attain high density, almost theoretical density; e.g. the density of the bulk material. These small pieces, e.g. tiles or sleeves (cylindrical segments), can be used to assemble a large target (target assembly). However, this approach presents several drawbacks. First, mounting the pieces should be done with controlled spacing over an appropriate backing structure, e.g. backing tube or backing plate (e.g. with compatible coefficient of thermal expansion). Bonding material should be provided and activated between the pieces and the backing structure (e.g. by melting of indium). In preferred instances, this bonding material should be conductive, for generating a conductive path. These issues are not limited to the manufacture of the target, as the assembled target may give troubles during its use. As the target is made of smaller pieces, the surface usually presents seams or edges between the smaller pieces. These edges are prone to arcing during sputtering, where a very high electrical field forms around the edge. Edges may be also more sensitive to defect formation (e.g. nodules, dust, . . . ). These nodules may have dielectric character and locally reduce the conductivity of the target surface. Also, the maximum achievable power level is often limited by the bonding material and quality of the bonding, and not by the target material itself. In some cases, binding compounds such as organic compounds are mixed in the target material to improve the integrity, but these result in contamination of the final target, which turns into contamination on the sputtered material on the substrate during use.

Moreover, due to manufacturing issues, not all pieces have exactly the same properties and performance, which affects the overall performance of the target. For example, this means that the pieces may be eroded during sputtering in an inhomogeneous way, so sputtering has to be stopped before the thinnest segment is fully consumed (retaining some intrinsic mechanical strength) and reducing target utilization. For example, although the pieces are supposed to have the same density, some pieces may have a deviating density and be more sensitive to arcing, powder or nodule formation, or potentially generating defects.
Additional problems raise for tubular shaped targets, namely:
Hard to guarantee good circumferential bonding
Bonding material may appear at the target surface through the gap between two segments (risk of contaminated sputtering)
Often need for expensive backing tube (e.g. titanium instead of stainless steel, due to the higher level of straightness and roundness of titanium, etc.)
Narrow tolerances on the inner diameter of the sleeve and outer diameter of the backing tube.

To overcome these issues, other techniques have been attempted to provide targets made of fewer pieces, e.g. of a single piece and having relatively large dimensions. One of these techniques is thermal spraying of material directly on a large backing structure.

Spraying is a proven technology for making larger size sputter targets, which can be implemented for several target geometries; e.g. cylindrical or flat targets. It is inherently related to the technology. Quite dense material layers can be generated. While for example cold spraying may rely on the plastic deformation of the source material (e.g. metals or metal alloys and compounds), thermal spraying acts on the melting of the source material.

Hence, thermal spraying allows realizing larger sized single piece targets with high density (e.g. typically more than 85%, more than 90%, even more than 95% of its theoretical density) for most metallic materials (pure, alloyed, . . . ) and even for some ceramic materials.

However, as thermal spraying requires the formation of droplets by partial and/or total melting of the projected material, it is challenging to provide coatings from materials that present difficult melting (e.g. high melting point temperature plus low thermal conductivity) or thermal stability issues. Some materials significantly decompose and/or sublimate at the spraying conditions resulting in substantial fume and dust formation. As a result, it is often difficult to achieve high-density coatings and hence it is difficult to manufacture a target comprising these materials. The targets obtained from these materials present a density lower than 90%, even lower than 80%, of the theoretical density.

It was found that materials which thermally decompose or sublimate at typical temperatures of thermal spraying, are more difficult to obtain. The sprayed product may have lower density and may often include pores, voids and/or inclusions such as dust on its surface and/or in the matrix, etc. These temperatures are defined in the range of pressures as the pressure present during spraying. Usually, thermal spraying submits the material to be sprayed at temperatures in the range or surpassing the melting point. These materials with melting point temperature close to the boiling point, and/or decomposition or sublimation, may be hard or virtually impossible to be thermally sprayed. It is not fully clear why sublimating materials can still be sprayed in some cases, but it is believed that strong drag from the flame, combined with superheating and out-of-equilibrium melting plays a role. It is also believed that other materials that can melt, but start decomposing before reaching the melting point (such as ITO), may still be sprayed thanks to superfast heating during spraying. However, this process results in severe feedstock decomposition, fumes and dust during thermal spraying. Hence, the sprayed target will have low density, porosity (voids or other components) and such, which give troubles during sputtering.

As a comparison, materials such as titanium dioxide and zirconium dioxide can be provided in coatings with high density, close to the theoretical density (e.g. >95% of the theoretical density for titanium dioxide TiOx and >92% of the theoretical density for zirconium oxide ZrOx). These materials melt without thermally decomposing and at much lower temperature than their boiling point. They do not present sublimation and show well defined melting and boiling point temperatures at atmospheric pressure, which is usually the pressure present during spraying.

The following table shows the density of some thermally sprayed targets vs the density of the bulk material and the percentage of this bulk density that the sprayed material achieves.

TABLE I
Bulk theoretical density vs measured density, and porosity.

| | Bulk material | Target measurement | | |
|---|---|---|---|---|
| | Density | Density | | Relative |
| | (g/cm³) | (g/cm³) | Porosity | density |
| AZO (2% Al) | 5.56 | 4.68 | 7.3% | 84.2% |
| ITO (10% Sn) | 7.14 | 5.56 | 15.8% | 78.4% |
| TiOx | 4.23 | 4.13 | 1.6% | 97.6% |
| ZrOx | 5.68 | 5.29 | 6.0% | 93.2% |

Clearly, ITO has a lower relative density and a higher porosity level than for example titanium or zirconium oxide. Aluminium-doped zinc oxide shows a reduction of relative density to values close to 85%.

Targets with a density lower than the theoretical density have relatively more surface bonds relative to bulk bonds, requiring lower energy to provide sputtering effect, so for a given energy density, more target atoms can be dislodged. This manifests as a higher sputter rate for given power level. However, low density also increases the porosity of the target. Pores may act as defect sites during an abnormal glow discharge, increasing the probability of arc events. Additionally, the surface is rougher and the electrical field distribution may be less uniform. Moreover, porosities may break open during the sputter removal process and release a pocket of gas, eject material or bring a spot of different composition to the surface (e.g. having another secondary electron emission yield). Low density targets are also more susceptible to be contaminated by dust. For example, in the case of targets made by thermal spraying, high amounts of fine dust can be trapped between splat contacts and/or porosities.

For some of these materials having lower density and, possibly, trapped dust, it has been observed that under specific sputtering conditions, insulating islands or particles form on the surface. For example nodules may form with increased resistance. Dust may also form and accumulate over time (hours or days) on the target surface and eventually may lead to increasing arcing rate and, as a consequence, unstable sputtering.

The present invention provides a highly dense sputtering target with at least one dimension of 600 mm or larger; e.g. 800 mm or larger, comprising material which is volatile, or in other words, it sublimates or it decomposes at temperatures close to melting temperature, or the difference between its melting and boiling temperatures is less than 30%. The density of the target is at least 90%, preferably at least 95% of the theoretical density.

In order to obtain a large target with high density, even from these target volatile materials, target material (comprising volatile target material) is applied to a supporting or backing structure by thermal spraying, for example to a backing structure being at least 600 mm, e.g. being at least 800 mm long (e.g. having a side or diagonal with these dimensions, or being a tube with that length). A target product is provided. The target product is then submitted to hot isostatic pressure (HIP), so the material on the target product is densified. The pressures can range from 10 MPa to higher than 200 MPa, at temperatures of hundreds of degrees, for example higher than 700 K, for example higher than 1000 K and extending beyond 1300 K, such as 1600 K. HIP is usually done in a special pressure chamber, and it can be done on objects with a suitable size. Where in embodiments of the present invention reference is made to “target product”, reference is made to a target before the HIP process has been carried out. The target product may be a sprayed target as such, in other words, a target obtained by thermal spraying which can be submitted to a HIP process without further preparation, or it may be a sprayed target after a further preparation of the surface, before the HIP process. After the HIP process, a densified target, also referred to as dense target, or simply sputtering target, is obtained.

In a first aspect, the present invention relates to a sputtering target for sputtering, where target material covers continuously, without seams, a length of at least 600 mm, for example 800 mm, 1 m, 2 m, or more, for example 4 m. In some embodiments, the length of the target material covers the majority, e.g. more than 50%, more than 75%, more than 80%, more than 90% or all, of a backing structure. For example, a target assembly can be obtained out of single large pieces. For example, the sputtering target can be used for sputtering as a single, individual piece, without smaller segments or tiles. These sputtering targets can be used to sputter large substrates such as glass panes or the like. The target material is advantageously sprayed material, which is subsequently, after being sprayed onto the backing structure, submitted to hot isostatic pressure (HIP). Thus, the sputtering target may include a backing structure with sprayed and densified target material for sputtering on top thereof. The target material has an overall target material density of at least 90%, e.g. at least 95% or at least 98% or at least 99% of its theoretical density. In accordance with embodiments of the present invention, at least 40% of the mass of the target material, e.g. at least 50%, at least 60%, at least 70%, at least 75%, at least 80%, at least 90% of the mass of the target material comprises so-called target volatile material. Target volatile material is material which has, at pressures close to atmospheric pressure, e.g. between 700 hPa and 1300 hPa, a sublimation temperature, or a melting temperature and an absolute boiling temperature or decomposition temperature, wherein the absolute boiling and/or decomposition temperature is lower than, or less than 30% higher than the melting temperature. The target material of a sputtering target in accordance with embodiments of the present invention comprises at least one target volatile material.

In one embodiment, no bonding layer is provided between the backing structure and the target material. The spraying and densifying per se create a bonding between the backing structure and the target material with interlinking structures from the roughness and mechanical locking, for example promoted by diffusion during spraying and the subsequent HIP process.

In alternative embodiments, a very thin adhesion or bonding layer is provided on the backing structure, before providing, e.g. spraying, the target material, to improve adhesion of the target material on the backing structure. The thickness of the bonding layer, its mechanical and its thermal properties can be tailored to buffer differences between the backing structure and the deposited target material. In particular, the material may be chosen so its thermal expansion coefficient (TEC) may be between the TEC of the backing structure and the TEC of the sprayed target material. Thus, the adhesion of the target material and its integrity are less affected by shrinkage effects.

The optional bonding layer or bond coat may comprise bonding material which has a melting temperature of at least 500° C., for example 900° C. or above, for example 1000° C. or above, which may be provided on the backing structure before spraying the target material. The bonding material may be provided by spraying. This is a fast and easy process, that provides a good interlinking between the backing structure and the target material. If present, the thickness of the bonding layer or bond coat may be 500 microns or less, for example 300 microns or less, for example 250 microns or less, or 150 microns or less, for example around 100 microns. In some embodiments, the material may comprise titanium, nickel, nickel-aluminum alloys, copper, or a combination thereof.

Providing a very thin bonding layer as in embodiments of the present invention is clearly different from bonding by soldering or otherwise attaching a separate piece of densified target material to a backing structure. A solder layer of material with melting temperatures under 500° C., will not be present between the backing structure and the target material in embodiments of the present invention.

If present, the bonding material may form a layer between the backing structure and the densified material. In some cases, the material may diffuse between the material of the backing structure and/or the material for sputtering, forming a composition gradient rather than a well-defined layer.

The target material may preferably be conductive, so sputtering at frequencies lower than RF can be provided. For example, it may include conductive material. For example, the target material may have a resistivity of 1000 Ohm·cm or less, preferably below 100 Ohm·cm, more preferably below 10 Ohm·cm, even lower than 1 Ohm·cm. It is an advantage of embodiments of the present invention that the target presents a conductivity high enough so that it can be used with low-frequency AC sputtering process, or even DC sputtering process, suitable for providing optical coatings. The resistivity can be measured by any of the methods referenced in FIG. 8 and FIG. 9 and respective paragraphs of the published application WO2020099438A1.

In embodiments of the present invention, the backing structure may be a flat or curved plate, thus providing a planar target. In some embodiments the backing structure may be cylindrical. It may comprise a conductive material (sufficiently conductive so sputtering is not hindered). For example, it may include stainless steel, which is inexpensive. It may comprise titanium, which presents good thermal and mechanical stability. It may also comprise copper. It may comprise materials with similar composition or the same composition as the target material. For example, an old target can be used as backing structure, thus providing a target refill. The present invention is not limited by these examples. The target material can be provided directly on the backing structure, without adhesive layer, or it can be provided on the backing structure after a bonding layer has been applied, e.g. by thermal spraying of the target material on the backing structure.

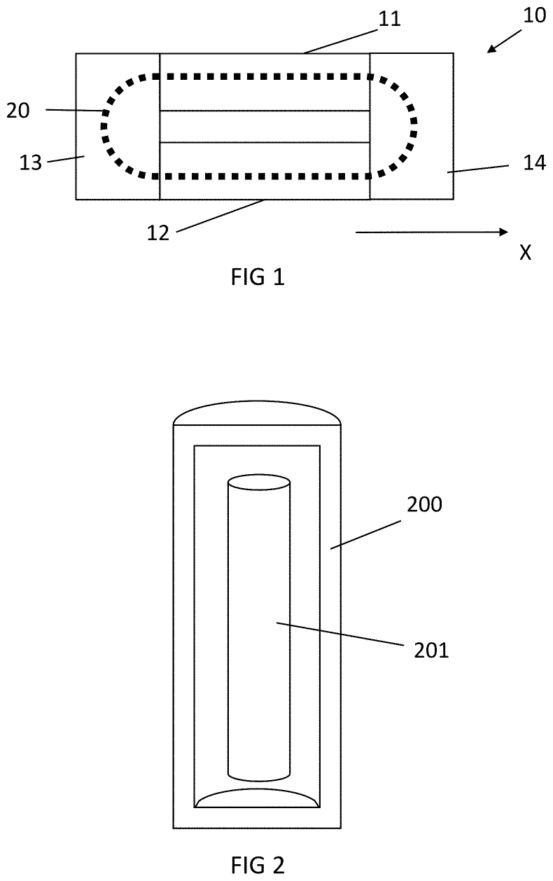

The sputtering target is preferably provided as a single piece which can be readily available for sputtering, with no need to assemble pieces. The present invention is not limited thereto, and a target may comprise more than one piece. For example, FIG. 1 shows an exemplary embodiment where a planar target 10 is provided with four pieces 11, 12, 13, 14, following a racetrack shape 20. At least the central pieces, which are the longest (X-direction) are usually formed by many tiles, in existing targets. In contrast, in embodiments of the present invention each central piece 11, 12 requires one single piece. They may cover more than half of the backing structure length.

In some embodiments, the target is a tubular target made as a single piece with an axial length of 600 mm or more, for example 800 mm, even up to 4 m. For example, it may be a tubular target with cylindrical shape.

Despite having such length and despite including target volatile material which presents pores after spraying, the present invention provides dense and large targets from sprayed materials.

In some embodiments, the target material includes SnO₂, ZnO, In₂O₃, WO₃ or a combination thereof as the target volatile material. In particular, the material may include ITO. It is noted that SnO₂ sublimates at 1800° C.-1900° C. while the melting point is 1630° C., so sublimation takes place at temperatures between 9.5% and 14.3% higher than the melting temperature. ZnO decomposes by sublimation at 1974° C., so the melting and boiling temperatures are considered the same (0% difference). In₂O₃ decomposes below 2000° C. while the melting point is 1910° C., so decomposition takes place at a temperature 4.5% higher than the melting point temperature. WO₃ shows a boiling point temperature at 1700° C. while the melting point is 1473° C., so the boiling temperature is around 13.3% higher than the melting temperature, although some sources indicate that tungsten oxide may sublimate below 750° C., between 200° C. and 1100° C., which is lower than the melting temperature. Indium tin oxide, depending on the exact composition, starts decomposing at around 900° C., while the melting temperature is typically considered higher, at around 1526-1926° C. Some conflicting data can be found in the literature regarding the above indicated threshold temperatures for these materials depending, among other factors, on oxygen partial pressure and humidity content.

The target material may comprise target volatile material for at least 40%, e.g. at least 50%, at least 60%, at least 70%, at least 80%, or at least 90% of its mass. The rest may be other material, such as a conductive material or other ceramic material, e.g. aluminum, alumina, zirconium, silicon . . . . In some embodiments, 100% of the target material is target volatile material.

The density of the target volatile material in the target material is at least 90%, e.g. at least 95%, at least 98% or at least 99% of the theoretical density of said material. The density of the target volatile material in the target can be obtained by measurements of the density of the total target material compared to the theoretical density. The calculation may be done by assuming that the non-volatile part of the target material after HIP processing is 100% of the theoretical density, i.e. the density is equal to the density of the bulk (non-volatile) material. This is, in general, correct for many materials such as metals. For example, if the total density of the target is at least 90% from the theoretical density from all of its comprising components, and if the claimed fraction is at least 40% of the mass of the target, the density corresponds with at least 80% of the theoretical density for the claimed fraction, while assuming 100% for the remaining fraction.

Additionally or alternatively, the porosity of the fraction of target volatile material can be obtained by metallographic analysis of a cross section of the target, from which the density of the corresponding portion can be calculated.

In other embodiments, the density of the target material is at least 90%, e.g. at least 95%, at least 98% or at least 99% of the theoretical density of the target material, including the target volatile material and any other materials therein.

The HIP process reduces the porosity of the target, for example trapped pores in the matrix may be scarce. Open pores on the surface can be removed by polishing, by coating or the like, after spraying and/or after the hot isostatic pressing. By reducing roughness and surface pores, arcing during sputtering is reduced when using the targets of the present invention. The presence of less pores embedded in the target allows that, even after erosion due to target consumption, surfaces can be still smooth and uniform, allowing uniform electric field distribution at the start and during the sputtering process. The presence of dust and trapped gas in the pores is reduced, so there are less contamination and dust accumulation issues. With a lower arcing rate, stable sputtering can be provided for a long time.

The target has a very high purity where 99.9% of the material is intended for sputtering, with very low contamination, because no binding agent may be required in the target material, as it is the case of some sintering methods.

In a second aspect of the present invention, a method of manufacturing a sputtering target is provided. The method includes thermally spraying target material to a backing structure, where at least part of the material is a target volatile material as explained previously. Thus, a target product is obtained, which will usually have lower density than the theoretical density, typically lower than 98%, for example lower than 90% or even lower than 85% of the theoretical density. Although spraying usually provides dense layers, and thus dense targets, a group of materials (referred to before as ‘target volatile materials’) rarely achieve high density layers, due to their high vapor pressure. These materials are usually ceramic, e.g. some metal oxides e.g. zinc, indium, tin or tungsten oxides as mentioned earlier.

The thus obtained target product, e.g. the sprayed target, will then subsequently be submitted to hot isostatic pressure thereby obtaining a pressed or densified target.

Hot isostatic pressure (HIP) process is a manufacturing process used to reduce the porosity and to increase the density of metals and many ceramic materials. This improves the material's mechanical properties and workability. The HIP process subjects a component to both elevated temperature and isostatic gas pressure in a high-pressure containment vessel. FIG. 2 shows an exemplary vessel 200 which provides the required temperature and pressure to a tubular target product 201 after thermal spraying. The pressurizing gas most widely used is argon. An inert gas is preferred to reduce chemical reaction of the material with its surrounding environment. The chamber is heated, causing the pressure inside the vessel to increase. Many systems use associated gas pumping to achieve the necessary pressure level. Pressure is applied to the material from all directions (hence the term “isostatic”).

The process is well known for metal casting from metal powders. The inert gas is applied between 50.7 MPa to 310 MPa, commonly 100 MPa. Process soak temperatures range from 482° C. (Al castings) to 1320° C. (Ni-based superalloys). The simultaneous application of heat and pressure eliminates internal voids and micro-porosity through a combination of plastic deformation, creep, and diffusion bonding, with improving fatigue resistance of the component. Primary applications are the reduction of micro-shrinkage, consolidation of powder metals, and metal cladding. The process can be also applied to ceramic composites, which gives similar results, albeit adapting the pressures and temperatures.

Thus, the HIP process can be applied to the target product of embodiments of the present invention to densify it. In some embodiments, the HIP process increases the density of the target by at least 5%, for example at least 10% or at least 15%, for example at least 20%. Thus, the pressed target will have a density of at least 90% of the theoretical density, for example at least 95% or at least 98% or at least 99% or even higher. Such densified target may be directly used for sputtering. However, in alternative embodiments, other intermediate and/or finishing steps can be provided on the densified target before using it for sputtering.

For example, the sprayed target may contain a high level of porosity on its surface. Smoothing the sprayed target surface by removing most or all of the open pores may be an intermediate step to obtain the target product. Also, after the hot isostatic pressing process, the target surface may be finished, e.g. by again smoothing it for removing remaining open pores, or removing any surface material that is not required.

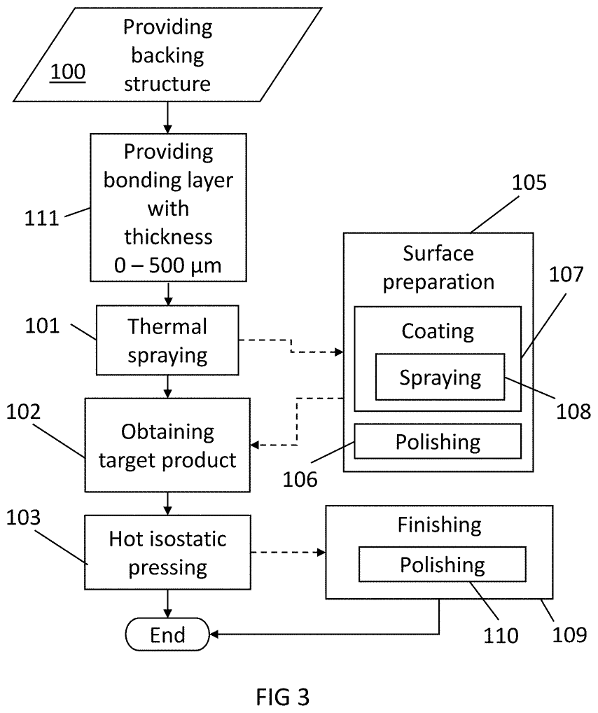

FIG. 3 shows a flowchart with exemplary steps to manufacture a sputtering target in accordance with embodiments of the present invention.

First, a backing structure is provided 100. It may be a plate, a tube or the like. It can even be a used target that needs to be refilled. In some embodiments, providing 100 a backing structure may comprise providing a single piece backing structure for providing a target piece of at least 600 mm, e.g. at least 800 mm, for example 1 m, or 2 m, or 4 m or more, for example a tube of 800 mm or more, thus allowing the provision of a single piece large target for sputtering large areas, such as glass panes or the like.

The backing structure may be provided 111 with a thin bonding layer, for instance a bonding layer of 500 μm or less, such as a bonding layer of 300 μm or less. Providing the bonding layer may be done by spraying high melting temperature material on the backing structure, which melts at temperatures of 500 degrees or higher. The characteristics of the bonding layer are specified below.

Target material, including target volatile material, is applied 101 to the backing structure by thermal spraying. The sprayed target material includes for at least 40% of its mass, e.g. at least 50%, at least 60%, for example at least 70% of his mass target volatile material, such as ZnO, In₂O₃, SnO₂, WO₃, or mixtures or compounds thereof; e.g. SnO₂ and In₂O₃; e.g. ITO comprises typically at least 80 wt % of In₂O₃ and less than 20 wt. % of SnO₂; for example in a 90:10 composition ratio. Other mixtures or compounds include tin oxide and indium, tin oxide and indium oxide, ITO and metallic tin. Some examples are given in paragraphs [0018], [0019], [0025] of patent EP2294241B1.

Thermally spraying a target may comprise plasma spraying, flame spraying, high velocity oxygen fuel spraying, or any other suitable technique.

From the sprayed target, a target product can be obtained 102. For example this target product may be a single piece with a dimension, e.g. a length, of 600 mm or more; e.g. 800 mm or more as explained earlier. In some embodiments, the sprayed target itself may be the target product which can be then submitted 103 to hot isostatic pressing (HIP). For example, if the initial density of the as-sprayed material is sufficiently high and/or does not contain open pores, the sprayed target may be placed in the HIP vessel “as is”.

In alternative embodiments, the sprayed target is submitted 105 to a further preparation step, for instance mainly a surface preparation, thereby obtaining a target product made of a single piece comprising target material. For example, this intermediate preparation step can be carried out if full densification cannot be achieved from the sprayed target “as is”; e.g. due to the presence of open pores.

For example, the intermediate step may comprise closing the surface open pores by grinding and/or polishing 106 the target. Polishing the target results in a smooth surface with a characteristic shine, which indicates that roughness is being reduced and that the density of open pores may be reduced as well.

Additionally or alternatively, the intermediate step may comprise coating 107 the surface of the sprayed target with a coating adapted to close the open pores, e.g. providing few layers of material so that surface pores close. In embodiments of the present invention, the pores are covered and closed, rather than infiltrated. Filling of the pores is less desired, because once they are filled the hot isostatic pressure processing cannot close them, and the density and homogeneity thereof is less controllable, and may thus be negatively affected. Infiltration of the pores may result in contamination of the target material with infiltrating material over a significant depth and may not be a desired situation. For example, layers of a thickness of 1 mm or less can be used, for example 500 μm or less, e.g. 300 μm or even thinner, e.g. 100 μm. This intermediate coating step can be done using an overlay material. The coating can be provided homogenously over the target material so the coating has a uniform thickness. In some embodiments, coating can be done by spraying 108, e.g. thermally spraying. However, the present invention is not limited to thermally spraying, and the further coating can be done by cold spraying, sputtering, vapor deposition, and any other technique compatible with the subsequent HIP process. Preferably, the coating does not cause degassing during HIP, advantageously providing a safe HIP process with less contamination to the vessel 200 (FIG. 2).

In some embodiments, the overlay material is a material different from the target material. For example, the overlay material may be a metal, e.g. a metal with a high melting point, such as higher than, e.g. at least 20% higher than, the maximum temperature attained during the HIP cycle, for example at least 30% higher. Example overlay materials may be stainless steel (which is relatively inexpensive) or titanium (which presents good strength under the HIP conditions submitted to the target thereafter) or nickel, or a metal alloy with sufficiently high melting point. However, the present invention is not limited to metals.

In some embodiments, the overlay material may be the same as the target material. This has the advantage that, after HIP, there is no need to remove the overlay material. For example, the overlay material may be provided also by spraying, e.g. thermal spraying, however spraying under different conditions that optimize densification over effective spraying (e.g. obtaining a high deposit efficiency) thus providing a capping layer with lower porosity than the underlaying target material. This has the advantage that the set-up does not need to be changed, e.g. the sprayed target does not need to be removed from the spraying chamber, only the spraying parameters need to be changed. It also has the advantage that there are no issues of incompatibility of expansion coefficients, as both materials are the same, thus reducing cracks or issues of shrinkage during the HIP process.

In an illustrative example, ITO can be provided with different spraying conditions. The material used to provide ITO targets is expensive. Usually, spraying conditions (plasma, temperature, feeding rate) are optimized to waste as little material as possible through the ventilation of the spraying chamber. However, it may be possible to tune the spraying conditions to improve the density so as to obtain a surface with low porosity, at the expense of higher quantity of wasted material. The present invention allows providing most of the target under conditions that save material (resulting in a suboptimal density), with a final step of providing few layers, for example up to half millimeter, one or two millimeters at the surface, under conditions that maximize density. Material is wasted at a higher rate but for a very limited time.

Thus, from the sprayed target, a target product can be obtained by preparing 105 the surface of the sprayed target. The HIP can be performed 103 directly on the target product.

In some embodiments, the target product can be optionally included in a canister. However, the canister needs to tightly fit the target product. By contrast, coating is provided directly on the surface, while a canister needs to be custom-designed to adapt to the surface topography. A canister also usually requires welding to the sprayed target and evacuating to vacuum, thus reducing contamination. Besides, it can bring problems of shrinkage. The mass used is larger than with coating, so it gives more shrinkage issues than a thin coating. In some embodiments of this invention, the canister is preferably not used, and the HIP process is performed directly on the surface of the target product.

Performing 103 a HIP cycle may comprise submitting the target product to very high pressures under well controlled heating, with ramp up, steady state and cooling profiles. The pressure may be e.g. 10 MPa or higher, e.g. at 50 MPa, 100 MPa, or over 200 MPa, or any value in between. The heating may be done e.g. up to 600 K, preferably hotter, e.g. up to 1000 K, or up to 1400 K or even higher, e.g. over 1800 K, or any value in between. The particular values of pressure and temperature depend on the material used. Typically, the temperatures need to be higher than for metals.

The HIP cycle is introduced for densifying the target material in order to achieve the advantages of a thermal sprayed target and of a sintered target. Thus, a single piece target of constant composition across the target can be provided, with no need for additional bonding (which may limit the maximum achievable power during sputtering). There is no need of presence of gaps over the target which would cause defects and arcing because the target may be provided as a single piece. Artifacts which typically appear on low density targets are reduced or avoided. These artifacts include e.g. nodule or dust formation, which lead to arcing and unstable processes, potentially giving defects in the deposited sputter coating.

The ceramic sputter target material can be densified to densities of at least 95%, for example denser than 97%, or than 98%, even denser than 99% of the theoretical density of the material (of the bulk material).

The HIP cycle can be designed and adapted to optimize some aspects of the densified target, while sustaining the integrity of the target. The densification allows reaching densities close to the theoretical density. Internal pores can be eliminated, which provide a smooth erosion profile and homogeneous sputtering for longer. Mechanical properties are also improved (improved ductility and/or resistance to fatigue or impact). The HIP process also improves bonding of the target material to the backing structure, e.g. bonding by diffusion to the backing structure. HIP may also contribute to stress relaxation of the sprayed layer.

A target manufactured by this method provides an improved performance under wider operating conditions. For example, these targets allow sputtering at higher power levels.

The design and adaptation of the HIP process includes temperature, pressure, as well as pressure profile and temperature profile during the HIP cycle (e.g. rate of heating/reheating, cooling, pressurization, etc.).

In some embodiments, the densified target can be readily used for sputtering. In alternative embodiments, the surface of the densified target may be optionally submitted 109 to a further treatment, thus finishing the target after the HIP process.

Removal of any contamination that may be induced by applying a capping layer, possibly containing undesired elements, can be done by submitting 109 the target to the finishing step, for example grinding and/or polishing 110, although other steps such as chemical treatment or the like can be used. Moreover, after performing the HIP process even if not using a capping layer, directly on the sprayed (and optionally polished) target, the top morphology of the target material (material closest to the surface) may deviate from its bulk properties. This part may advantageously be removed. For example, performing the HIP cycle without the capping layer may retain some porosity at the top (open pores with limited extent into the material), while deeper voids were originally already closed pores and became densified.

For example, the further treatment may comprise removing the overlaying protective layer. If a coating with material different from the target material is used, finishing the process may include removing from the target the first layers including the coating material. Hence, a dense target with at least one dimension being at least 600 mm, e.g. 800 mm can be obtained (e.g. an axial length for a tubular target, a side or a diagonal of a rectangular or square target), for example a single target as large as the backing structure, seamless and in one piece, or at least with very few tiles in large planar targets where at least one piece has a dimension which is more than 50%, for example being as large as, one dimension of the backing structure of the whole target. The density can be 90% or higher, e.g. 95% or higher, even if target volatile materials are used as target material, e.g. more than 40% or 50% or 60% or 70%, e.g. more than 80% or even at least 90% of the target material is a volatile ceramic material.

The method of the present invention may be used to manufacture tubular targets or planar targets. The backing structure can be non-flat. For example, it may be concave. For example, it may be a bent plate. For example, it may be a mold or block with a groove for accumulating material, for providing material mainly on the zones where most material will be sputtered away.

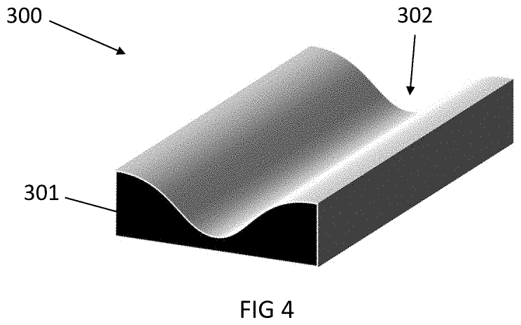

A detail of such backing structure is shown in FIG. 4. The structure 300 may be a block 301 with a groove 302, e.g. a smooth groove with sinusoidal or gaussian shape or the like. The direction of the groove 302 may be adapted to follow the racetrack when the block 301 is being used as a backing structure of a target during a sputtering process, as the relative position between the magnets and the block in the sputtering device determines the position of the racetrack and it can be predetermined. Spraying the backing structure 300 has the advantage that the material can be selectively provided on the structure 300. This means that the groove 302 may receive much more sprayed material than the areas at the sides of the groove 302.

FIG. 5 shows two schematic routes of thermal spraying and HIP on a concave backing structure. The top drawing 501 shows a cross section of the block 301 of FIG. 4. The leftmost middle drawing 502 shows target material 303 comprising target volatile material, having been thermally sprayed on the block 301 thus forming a sprayed target product 401. In the embodiment shown in FIG. 5, the spraying of layers is not homogeneous by design. It is made so that the largest thickness of the sprayed layers of target material 303 is close to or coincides with the deepest point of the groove. As the sprayed material comprises a substantial amount of target volatile material (e.g. 60% or more) as explained in the first aspect of the present invention, the density is lower than the theoretical density of the material, with a high level of porosity. At this point, if the amount of surface pores is small (or after removing the open pores by post-processing, such as polishing), then the target product can be submitted to HIP. The target material densifies, e.g. becomes up to 20% more dense with respect to the theoretical density; pores are removed from the sprayed material thus forming dense target material 304, the volume decreases and the profile 305 flattens, as shown in the leftmost lowest drawing 503. Thus, the target 402 has target material mainly on the area where the racetrack is generated (thus, in the zone of highest erosion). This allows a very efficient utilization of target material during a subsequent sputter process.

In some embodiments, an optional surface treatment, coating or capping layer 306 can be provided on the sprayed material 303 before submitting the target product to the HIP process, as shown in the rightmost top drawing 504 of FIG. 5. This coating of overlay material can be used to close any open pore in the material, for example by providing material on top so the open pores become closed, so there is no need to provide material with tailored viscosity and surface tension to fill the pores. As explained earlier with reference to the method steps of surface preparation 105 (FIG. 3), specifically of coating 107, this surface preparation may be done by spraying 108, for example cold or thermal spraying, or by other means; the coating provides a capping layer 306 which has lower porosity than the underlying surface of the sprayed target, and with a homogeneous thickness, for example a thickness of 1 mm or less, e.g. down to 100 microns. In some embodiments it is thicker than 0.5 mm. The overlay material may be a material different from the target material (e.g. metal), or it may comprise some of the materials of the target material, or it may be the same material but provided in a way in which density is optimized. The coated sprayed target product 403 can be submitted to a HIP process as before, so the profile flattens thus providing dense target material layers 304, where target material is provided mainly on the erosion zone, as shown in the lowest rightmost drawing 505. If the overlay material is the same as the target material, the target 404 obtained after HIP process can be used as such to sputter. Otherwise, it is possible to perform a finishing step by removing the after-HIP capping layer 316 as explained earlier, thus obtaining a target 402 without overlay material. In case of tubular targets, the finishing step may comprise providing a cylindrical shape to the tubular target, e.g. by grinding or the like. In some embodiments the target may be a dogbone shape tubular target in accordance with the performance of the magnetron on which the target is planned to be used.

In alternative embodiments, the backing structure may be convex, for example a tubular target, the present invention not being limited to cylindrical shapes. Optionally, as with the case of planar targets, the shape of the convex target may be thinner on the opposite extreme ends, where more erosion takes place. As before, spraying may be adapted so a larger amount of material is provided on the zones of larger erosion.

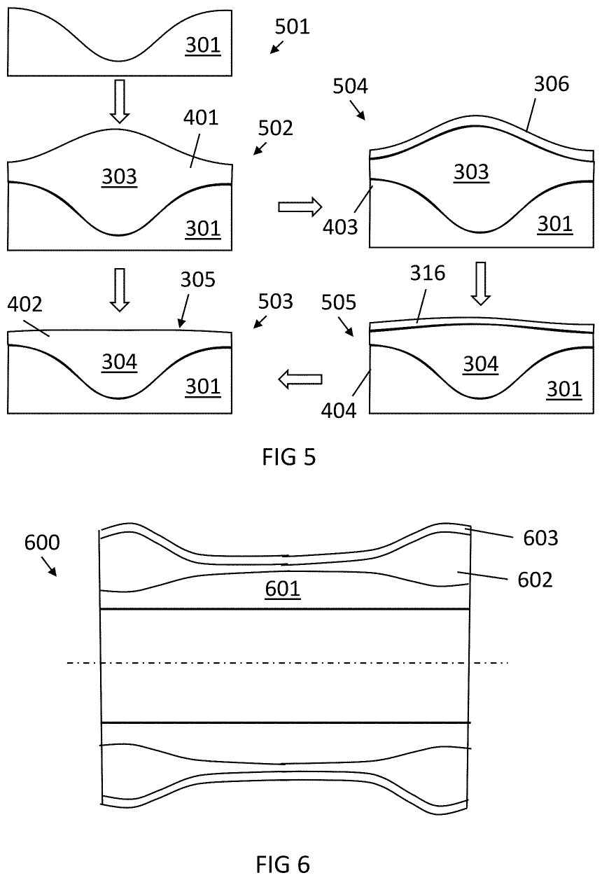

FIG. 6 shows a longitudinal cross section of a sprayed target product 600 with a tubular shape, comprising a hollow tubular backing structure 601 and sprayed layers of target material 602 covering the backing structure 601. In this and later figures, the central axis of the body is indicated by a dash-dot line. The hollow tubular backing structure may be molded, extruded, rolled, and may be preferentially straight. In some embodiments of the present invention, the molded backing structure 601 is thinner at the ends, where a higher amount of material 602 has been sprayed on top. The sprayed target product 600 of FIG. 6 shows an optional capping layer 603 of dense overlay material for reducing or removing porosity from the surface of the target product, analogously to the coating 306 of planar targets.

The target product 600, obtained after spraying, can be submitted to HIP processing as described previously. The resulting target will be a tubular target, substantially cylindrical due to the increase of density with reduction of volume, especially at the ends where the mold presents molded grooves. A specific finish step can be applied, for example the capping layer 603 after HIP can be removed if needed, as explained earlier. Another finishing step may be performed at the inside of the tubular backing structure 600 to provide the desired inner diameter properties.

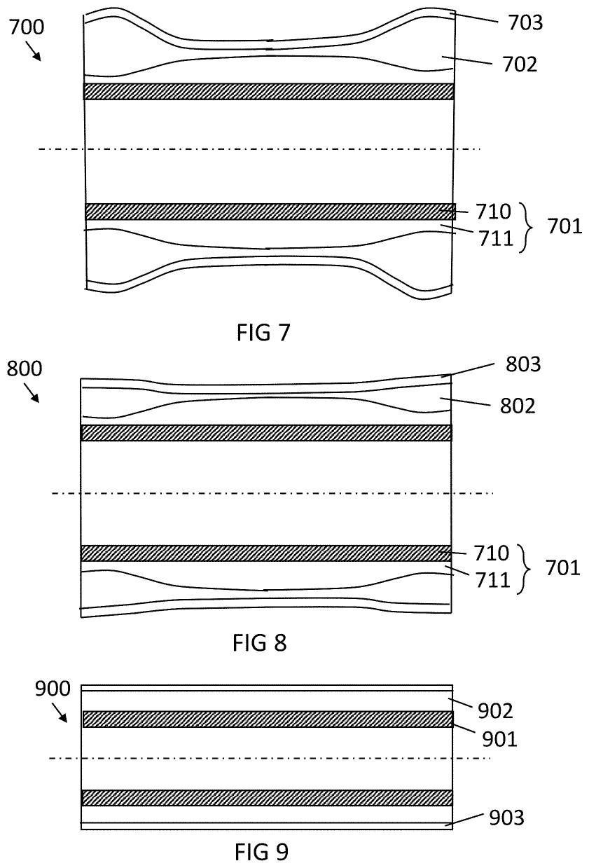

FIG. 7 shows a cross section of an alternative embodiment, where the sprayed target product 700 comprises sprayed material 702 provided on an eroded target 701 which needs to be refilled. This eroded target includes a carrier 710, which is a hollow tube, and eroded material 711 covering the carrier 710. As in the case of the molded backing structure 601, the ends are thinned, in this case due to the stronger erosion at the ends of the target due to the shape of the racetrack, during sputtering. The sprayed material is provided mainly over the eroded grooves, although a thinner layer may be sprayed over the rest of the material. Preferably, the sprayed target material 702 is the same material as the material 711 in the backing structure, covering the carrier 710. As before, an optional capping layer 703 may be provided to close open pores on the surface before the HIP process.

The resulting target 800 after the HIP process is shown in FIG. 8. The sprayed target material 702 is densified, the volume decreases and the profile flattens so a highly dense material 802 is provided around the backing structure 701. The surface becomes regular with a cylindrical profile, with constant or almost constant radius. As before, the capping layer 803 after HIP can be optionally removed.

In some embodiments, as shown in e.g. FIG. 6, providing a backing structure comprises providing a metal structure, e.g. a metal carrier. For example it may be an inexpensive structure, e.g. stainless steel. It may be a structure comprising material which presents a strength against the HIP conditions. For example, it may comprise titanium. In some embodiments, the backing structure comprises material with a compatible thermal expansion coefficient.

The method may be applied to obtain tubular targets 900 with a traditional carrier. For example, as shown in FIG. 9, the backing structure 901 may be a tubular structure, e.g. a carrier, with cylindrical shape, and the target material 902 is provided homogeneously over the surface of the backing structure 901, by thermal spraying and a subsequent HIP process. An optional capping layer 903 may be provided also.

In some embodiments, providing a backing structure comprises providing a bonding layer for better and more controlled adhesion of the (volatile) target material, e.g. onto a carrier such as a backing tube. Furthermore, a bonding layer may be chosen to be sufficiently thick and having mechanical and thermal properties to buffer differences between the backing structure and the deposited target material. For example, the bonding layer may have a TEC being between the TEC of the backing structure and of the sprayed target material. This may be especially important for maintaining good adhesion after performing the HIP cycle.

The optional bonding layer may be provided on the backing structure by spraying, before providing the target material for sputtering, e.g. before spraying and densifying the target material. Providing the bonding layer may comprise providing material with a high melting temperature in sprayable form, and spraying it on the backing structure. A thin bonding layer, for example a layer with a thickness of 500 microns or less, for example 300 microns or less, for example 250 microns or less, or 150 microns or less, for example around 100 microns, may be provided. For example, the material may have a melting temperature of at least 500° C., for example at least 900° C., for example at least 1000° C. In some embodiments, the material may comprise titanium, nickel, nickel-aluminum alloys, copper, or a combination thereof.

The high melting temperature ensures that bonding will occur at least during the subsequent spraying of material to form the sprayed product. In some cases, in the end product, the bonding material will be present as a layer between the backing structure and the densified material, after the HIP process, thanks to the relatively high melting temperature of the bonding material. In alternative cases, the material may diffuse between the material of the backing structure and/or the material for sputtering, forming a composition gradient rather than a layer, further improving bonding between the material for sputtering and the backing structure.

However, the method of the present invention is not limited to the use of a bonding layer, and target material can be directly sprayed on the bare backing structure material for providing the sprayed product, before HIP.

In some embodiments, the material of the bonding layer may comprise or consist of the same material as the target material. For example the target material in the example of FIG. 6 may be the same as the material used to provide the molded backing structure. In some embodiments, the method of manufacturing the target comprises refilling a used target as shown with reference to FIG. 7 and FIG. 8. The backing structures 300 shown in FIG. 4, FIG. 5, may also comprise used targets, e.g. comprising a carrier and remaining uneroded material, where the grooves are actually erosion grooves generated by a plasma racetrack during previous sputtering of the target.

Thus, the present method of manufacturing of targets may be used to restore large targets with highly dense target material, with a density close to theoretical density, where the target material comprises volatile ceramic material. The method can also be used for refilling targets originally prepared by sintering, e.g. where the backing structure comprises smaller tiles.

It is noted that the sputtering target of the first aspect of the present invention may be provided in accordance with embodiment of the method of the second aspect of the present invention. Thus, the sputtering target of the present invention may be a sprayed and hot-isostatic pressed sputtering target, not a sintered target.

1.-16. (canceled)

17. A sputtering target comprising at least one single piece with a length of at least 600 mm, the sputtering target comprising a backing structure provided with target material for sputtering, wherein at least 40% of the mass, of this target material comprises a target volatile material wherein the target volatile material shows, at pressures between 700 hPa and 1300 hPa, either
a sublimation temperature, or
a melting temperature and an absolute boiling or decomposition temperature,
the absolute boiling and/or decomposition temperature of said target volatile material being less than 30% higher, or being lower, than its melting temperature, the target material having an overall target material density of at least 95%, of its theoretical density,
wherein the sputtering target comprises a bonding layer with a thickness of 0 μm to 500 μm between the backing structure and the target material.

18. The sputtering target of claim 17, wherein at least 60% of the mass of the target material comprises target volatile material.

19. The sputtering target of claim 17, wherein the target volatile material for sputtering is a ceramic material.

20. The sputtering target of claim 19, wherein the target volatile material for sputtering is a metal oxide such as indium tin oxide, ZnO, or SnO2, or In2O3, or WO3 or other metal oxides.

21. The sputtering target of claim 17, wherein the target material has a resistivity lower than 1000 Ohm·cm.

22. The sputtering target of claim 17, wherein the backing structure has a thermal expansion coefficient similar to the thermal expansion coefficient of the target material, and/or wherein the backing structure is made of steel.

23. The sputtering target of claim 17, wherein the sputtering target is a cylindrical target.

24. The sputtering target of claim 17, wherein the backing structure has a tubular shape.

25. A method of providing a target for sputtering, the method comprising providing a backing structure, optionally providing a bonding layer with a thickness of 500 μm or less onto the backing structure, thermal-spraying target material over the backing structure with the optionally provided bonding layer,
wherein at least part of the target material either sublimates or the absolute boiling or decomposition temperature of said material is less than 30% higher or even lower than its melting temperature, thus obtaining a target product, and subsequently performing a hot isostatic pressure process on the target product, thus increasing the density of the target product to at least 95% of its theoretical density.

26. The method of claim 25, further comprising a preparation step on the surface of the target material before performing hot isostatic pressing.

27. The method of claim 26, wherein the preparation step comprises polishing, grinding or removing surface material thus providing lower surface porosity.

28. The method of claim 25, further comprising coating the sprayed target with material thus providing an external layer with high density.

29. The method of claim 25, further comprising removing an external layer of the provided target after performing the hot isostatic pressure process.

30. The method of claim 25, wherein providing a backing structure comprises providing a backing structure with a length of at least 600 mm.

31. An application of the method of claim 25 for providing a sputtering target in accordance with a sputtering target comprising at least one single piece with a length of at least 600 mm, the sputtering target comprising a backing structure provided with target material for sputtering, wherein at least 40% of the mass, of this target material comprises a target volatile material wherein the target volatile material shows, at pressures between 700 hPa and 1300 hPa, either
a sublimation temperature, or
a melting temperature and an absolute boiling or decomposition temperature,
the absolute boiling and/or decomposition temperature of said target volatile material being less than 30% higher, or being lower, than its melting temperature, the target material having an overall target material density of at least 95%, of its theoretical density,
wherein the sputtering target comprises a bonding layer with a thickness of 0 μm to 500 μm between the backing structure and the target material.

32. A sputtering target obtained by the method of claim 25.
